(19) United States
(12) Patent Application Publication
(10) Pub. No.: US 2008/0075856 A1
(43) Pub. Date: Mar. 27, 2008

(54) Deposition apparatus, deposition method, method of manufacturing liquid crystal device

(75) Inventor: Hiroyuki Kojima, Suwa-shi (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/904,147

(22) Filed: Sep. 26, 2007

(30) Foreign Application Priority Data
Sep. 27, 2006 (JP) 2006-262327
Feb. 28, 2007 (JP) 2007-048624
Aug. 30, 2007 (JP) 2007-223540

(51) Int. Cl. C23C 16/04

(52) U.S. Cl. 427/255.5; 118/720

(57) ABSTRACT

There is provided a method of manufacturing a liquid crystal device, in which an inorganic alignment film is deposited on the surface of a substrate by allowing a vapor, which is generated by heating a deposition material, to reach the surface of the substrate through a slit hole so as to form a predetermined angle, the substrate being opposed to the deposition material with a mask having the slit hole interposed therebetween and moving in two opposite directions, wherein the inorganic alignment film is selectively deposited only when the substrate moves in one direction of the two opposite directions.

### BACKGROUND

1. Technical Field

The present invention relates to a deposition apparatus, a deposition method, and a method of manufacturing a liquid crystal device, and more particularly, to the deposition apparatus, the deposition method, and the method of manufacturing the liquid crystal device forming an inorganic alignment film.

2. Related Art

Generally, as an alignment film for controlling an alignment of liquid crystal molecules in a liquid crystal device such as a liquid crystal display panel; there is a known inorganic alignment film such as an oblique alignment deposition film which is formed by depositing an inorganic material such as SiO on a substrate surface so as to form a predetermined angle.

However, in the oblique alignment deposition film, distances, angles, and directions from a deposition source to the various portions of a substrate surface are different. Accordingly, as a substrate becomes larger, uniformity of an alignment film on the substrate surface becomes more deteriorated. When the alignment film is nonuniform, variation in an alignment direction and a pretilt angle of the liquid crystal molecules on the substrate may occur. Accordingly, electro-optical characteristics of a liquid crystal cell vary in accordance with the various portions of the substrate surface. In order to improve the uniformity of the alignment film, it is required to increase a distance between a deposition material and the substrate. However, when the distance increases, a size of an apparatus becomes larger, and thus manufacturing cost also increases.

In order to solve the above-described problem, a method of performing a deposition process through a slit on a substrate moving in the rear of a shielding plate by providing the shielding plate with the slit between the deposition source (deposition material) and the substrate is disclosed in JP-A-54-46576, JP-A-63-172121, and JP-A-2006-330656. According to the method disclosed in JP-A-54-46576, JP-A-63-172121, and JP-A-2006-330656, the alignment film in which a deposition angle is uniform can be obtained since the deposition angle is limited due to a width.

A deposition method is a method of allowing vapor of the deposition material to travel in order to deposit the deposition material on the substrate. In addition, in a deposition apparatus, the deposition material is deposited on some positions in addition to the substrate in a vacuum chamber. A deposition material deposited on other portions other than a surface on which a film is to be formed by the deposition process in this way refers to an undesirable deposition material.

Since the undesirable deposition material easily peels off in a case where the deposition becomes a predetermined thickness, the undesirable deposition material may be a cause of foreign substances in the vacuum chamber. Accordingly, it is required to periodically remove the undesirable deposition material in the vacuum chamber.

When the undesirable deposition material is deposited on an inner wall surface of the vacuum chamber, it is required to stop the deposition apparatus in order to perform removal of the undesirable deposition material, thereby decreasing efficiency of the apparatus. Accordingly, in the vacuum chamber, the inner wall surface of the vacuum chamber is typically covered with an attachment-preventing plate which can be easily exchanged. In addition, the attachment-preventing plate also has a function of preventing the undesirable deposition material from being attached to movement units or wire portions formed in the vacuum chamber. It is possible to prevent working efficiency of the apparatus from decreasing by detaching the attachment-preventing plate in order to remove the undesirable deposition material on the outside of the deposition apparatus.

A technique for realizing a method of removing the undesirable deposition material attached to such an attachment-preventing plate in the vacuum chamber without damaging a vacuum state is disclosed in JP-A-6-128726. In the technique disclosed in JP-A-6-128726, the undesirable deposition material can be removed by heating the attachment-preventing plate and melting the undesirable deposition material.

When the oblique alignment deposition film is deposited on the substrate through the slit, as disclosed in JP-A-54-46576, JP-A-63-172121, and JP-A-2006-330656, a method of obtaining a predetermined film thickness by reciprocating the substrate several times to reiterate the deposition is used. That is because a film of sufficient thickness cannot be deposited just by moving the substrate in one direction only once.

However, in the oblique alignment deposition film formed by the above-described method, when pretilt angles of the entire substrate surface are measured, variation in the pretilt angles may be relatively large. As shown in FIG. 9, it is considered that the reason for this is that a movement of a substrate 135 during a deposition process causes alignment of molecules constituting an oblique alignment deposition film 116 deposited on a substrate surface 135b of the substrate 135 to be nonuniform.

When a movement unit for moving the substrate is provided in the vacuum chamber, and particularly when a substrate support mechanism for supporting the plurality of substrates and rotating them is provided in the vacuum chamber, as disclosed in JP-A-2006-330656, the deposition apparatus becomes more complex and a size thereof increases. Accordingly, manufacturing cost may increase.

When a complex substrate support mechanism having such a movement unit is provided in the vacuum chamber, the undesirable deposition material may be easily deposited on the movement unit. Accordingly, reliability of the apparatus may be reduced. Moreover, when periodically removing the undesirable deposition material, disassembling the movement unit or the like takes time. Accordingly, the working efficiency of the deposition apparatus may be reduced.

Meanwhile, when the plurality of attachment-preventing plates are each provided with heaters in the vacuum chamber, as disclosed in JP-A-6-128726, it is required to form wire lines that connect to the heaters in the vacuum chamber. When the wire lines are formed in the vacuum chamber in this way, the undesirable deposition material is also deposited on the wire lines. Accordingly, the reliability of the apparatus may be reduced. Moreover, since a mechanism for collecting the stacked undesirable deposition material is necessary, the deposition apparatus may become more complex and the size thereof may increase.

### SUMMARY

An advantage of some aspects of the invention is that it provides a deposition apparatus, a deposition method, and a method of manufacturing a liquid crystal device capable of forming a uniform alignment film and also preventing variation in pretlit angles on a substrate surface and capable of restraining an effect of an undesirable deposition material using a simple mechanism and also preventing efficiency of the apparatus from reducing.

According to an aspect of the invention, there is provided a method of manufacturing a liquid crystal device, in which an inorganic alignment film is deposited on the surface of a substrate by allowing a vapor, which is generated by heating a deposition material, to reach the surface of the substrate through a slit hole so as to form a predetermined angle, the substrate being opposed to the deposition material with a mask having the slit hole interposed therebetween and moving in two opposite directions, wherein the inorganic alignment film is selectively deposited only when the substrate moves in one direction of the two opposite directions.

According to the above-described method, the inorganic alignment film can be stacked without influence of the movement direction of the substrate. Accordingly, since the inorganic alignment film is formed in a regular and uniform pattern, it is possible to prevent the variation in pretilt angles on the surface of the substrate.

In the method of manufacturing the liquid crystal device, the two opposite directions in which the substrate moves may be parallel to a line obtained by projecting a segment connecting the center of the deposition material to the center of the slit hole onto the substrate surface in the normal line direction of the substrate surface, and the inorganic alignment film may be deposited when the substrate moves in the same direction as a flow direction of the vapor of the deposition material.

In the method of manufacturing the liquid crystal device, the two opposite directions in which the substrate moves may be parallel to a line obtained by projecting a segment connecting the center of the deposition material to the center of the slit hole onto the substrate surface in the normal line direction of the substrate surface, and the inorganic alignment film may be deposited when the substrate moves in the direction opposite to a flow direction of the vapor of the deposition material.

In the above-described method, the inorganic alignment film is formed by stacking a layer having a structure in which deposition molecules are uniformly arranged. Accordingly, the variation in the alignment of the molecules constituting the inorganic alignment film is smaller. That is, the deposition process of the inorganic alignment film is selectively performed only when the substrate moves in one direction, and therefore the inorganic alignment film has directivity. As a result, it is possible to restrain the variation in the pretilt angles more than that in the known example.

According to another aspect of the invention, there is provided a deposition apparatus for forming a thin film on a surface of a substrate by allowing vapor generated by heating a deposition material in a vacuum chamber to reach the surface of the substrate, the deposition apparatus including: an attachment-preventing plate having a conical or pyramidal opening formed toward the deposition material, being enlarged in an opening direction, and having a slit hole extending toward the opening in a side surface thereof; and a substrate support portion supporting the substrate so that the substrate is opposed to an outer surface of the attachment-preventing plate and the substrate is opposed to the deposition material at a predetermined angle, wherein the thin film is formed on the substrate by relatively rotating the attachment-preventing plate relative to the substrate support portion about a straight line passing through the center of the deposition material, and allowing the substrate supported by the substrate support portion to be exposed to the deposition material through the slit hole.

According to the deposition apparatus having the above-described configuration, the uniform inorganic alignment film can be obtained by performing the deposition process through the slit hole. In this case, an undesirable deposition material traveling in an upward direction from the attachment-preventing plate is an only deposition passing through the slit hole. In this way, since an amount of undesirable deposition material deposited on an inner wall of the vacuum chamber can be restrained, it is possible to prevent the undesirable deposition material from affecting an operation of the deposition apparatus.

Moreover, since the attachment-preventing plate on which the undesirable deposition material is deposited has a substantially conical shape, the attachment-preventing plate can collect a larger amount of undesirable deposition material. That is because the attachment-preventing plate has a broader area than a known attachment-preventing plate with a flat shape. That is, the attachment-preventing plate carries out the function of collecting the undesirable deposition material for a longer time and it is possible to lengthen an interval of a removing working of the undesirable deposition material deposited on the attachment-preventing plate.

In the deposition apparatus with the above-described configuration, a period of time to stop the operation of the deposition apparatus can be shortened, and thus it is possible to improve the efficiency of the apparatus. Further, the attachment-preventing plate with the substantially conical shape can be made by a bending working of a steel sheet.

The deposition apparatus with the above-described configuration may further include a rotating unit rotating the attachment-preventing plate. In the deposition apparatus, the attachment-preventing plate may be configured to be easily attached and detached to and from the rotating unit.

In the deposition apparatus with such a configuration, a working of taking out the attachment-preventing plate from the vacuum chamber or installing it can be easily completed for a short time. Accordingly, if an additional attachment-preventing plate with the substantially same shape on which the undesirable deposition material is not deposited is prepared in advance at the time of removing the undesirable deposition material deposited on the attachment-preventing plate, it is possible to resume the deposition apparatus just by substituting the attachment-preventing plate.

In this case, it is possible to remove the undesirable deposition material on the attachment-preventing plate which is taken out from the vacuum chamber in turn independent of the operation of the deposition apparatus outside. That is, it is possible to remove the undesirable deposition material deposited on the attachment-preventing plate in the outside of the apparatus and to substitute the attachment-preventing plate for a short time. As a result, it is possible to further improve the operational efficiency of the deposition apparatus.

A rotating unit is a rotating mechanism with only one axis like that in the known example. Accordingly, reliability of the deposition apparatus with such a mechanism is not reduced. Moreover, the simple mechanism facilitates a maintenance operation and a non-operation time of the deposition apparatus can be more shortened if a problem arises.

In the deposition apparatus with the above-described configuration, a plurality of the slit holes may be formed radially when the attachment-preventing plate is viewed from the opening side.

According to the deposition apparatus with such a configuration, it is possible to improve throughput of the deposition apparatus per unit time.

In the deposition apparatus with the above-described configuration, the substrate support portion may support the substrate at a plurality of positions in a circumferential direction about the central axis of the attachment-preventing plate and opposite the outer surface of the attachment-preventing plate.

According to the deposition apparatus with such a configuration, it is possible to improve throughput of the deposition apparatus per the unit time.

In the deposition apparatus with the above-described configuration, the substrate may be a substrate for a liquid crystal device and the thin film is an inorganic alignment film controlling alignment of liquid crystal.

According to the deposition apparatus with such a configuration, it is possible to form the inorganic alignment film of the liquid crystal device uniformly and efficiently. Accordingly, it is possible to provide the liquid crystal device with a high display quality at a low price.

According to still another aspect of the invention, there is provided a deposition apparatus for forming a thin film on a surface of a substrate by allowing vapor generated by heating a deposition material in a vacuum chamber to reach the surface of the substrate, the deposition apparatus including: an attachment-preventing plate having a conical or pyramidal opening formed toward the deposition material, being enlarged in an opening direction, and having a slit hole extending toward the opening in a side surface thereof; and a substrate support portion supporting the substrate so that the substrate is opposed to an outer surface of the attachment-preventing plate and the substrate is opposed to the deposition material at a predetermined angle, wherein the thin film is formed on the substrate by relatively rotating the attachment-preventing plate relative to the substrate support portion in one direction about a straight line passing through the center of the deposition material, and allowing the substrate supported by the substrate support portion to be exposed to the deposition material through the slit hole.

According to the deposition apparatus with such a configuration, the uniform inorganic alignment film is obtained by performing the deposition process through the slit hole while rotating the attachment-preventing plate in one direction. Moreover, since it is possible to perform a successive deposition process by rotating the attachment-preventing plate in one direction, productivity is excellent.

In the deposition apparatus with the above-described configuration, the substrate support portion may support the substrate so that the surface of the substrate and a side surface of the attachment-preventing plate are parallel to each other.

In the deposition apparatus with the above-described configuration, a width of a top end of the slit hole may be different from that of a bottom end thereof.

According to the deposition apparatus with such a configuration, it is possible to form a deposition film with a uniform thickness of the film on the surface of the substrate.

According to still another aspect of the invention, there is provided a deposition method of forming a thin film on a surface of a substrate using the deposition apparatus according to Claim 9, the deposition method including: rotating an attachment-preventing plate in one direction about a central axis, which is a straight line passing through the center of a deposition material, relative to a substrate support portion; and depositing the thin film on the surface of the substrate supported by the substrate support portion through a slit hole using the deposition material.

According to the above-described method of forming the thin film, it is possible to form the inorganic alignment film regularly and uniformly on the surface of the substrate by rotating the attachment-preventing plate in one direction. Accordingly, it is possible to restrain the variation in the pretilt angels in the surface of the substrate. Moreover, since it is possible to successively form the inorganic alignment film, the productivity is excellent.

According to still another aspect of the invention, there is provided a method of manufacturing a liquid crystal device forming a thin film on a surface of a substrate by allowing vapor generated by heating a deposition material in a vacuum chamber to reach the surface of the substrate, the method including: arranging the substrate on a substrate support portion opposed to a side surface of an attachment-preventing plate having a conical or pyramidal opening formed toward the deposition material, being enlarged in an opening direction, and having a slit hole extending toward the opening in the side surface; rotating the attachment-preventing plate only in one direction relatively relative to the substrate support portion about a central axis, which is a straight line passing through the center of the deposition material; and depositing the thin film on the surface of the substrate supported by the substrate support portion through the slit hole using the deposition material.

According to the above-described method of manufacturing the liquid crystal device, it is possible to form the oblique alignment deposition film, which is the inorganic alignment film, regularly and uniformly on the surface of the substrate by rotating the attachment-preventing plate in one direction. Accordingly, it is possible to restrain the variation in the pretilt angles in the surface of the substrate. Moreover, since it is possible to successively form the inorganic alignment film, the productivity is excellent.

### BRIEF DESCRIPTION OF THE DRAWINGS

The invention will be described with reference to the accompanying drawings, wherein like numbers reference like elements.

FIG. 1 is a top view illustrating a liquid crystal device when a TFT array substrate and elements formed thereon are viewed from a counter substrate.

FIG. 2 is a sectional view illustrating the liquid crystal device taken along the line H-H′ shown in FIG. 1.

FIG. 3 is a top view illustrating a mother substrate.

FIG. 4 is a schematic sectional view illustrating a configuration of a deposition apparatus.

FIG. 5 is a flowchart showing a process of depositing an inorganic alignment film.

FIGS. 6A and 6B are schematic diagrams illustrating an alignment of molecules of the inorganic alignment film.

FIG. 7 is a flowchart showing a process of depositing an inorganic alignment film according to a second embodiment.

FIGS. 8A and 8B are schematic diagrams illustrating the alignment of molecules of the inorganic alignment film according to the second embodiment.

FIG. 9 is a schematic diagram illustrating the alignment of the molecules of a known inorganic alignment film.

FIG. 10 is a schematic sectional view illustrating a configuration of the deposition apparatus.

FIG. 11 is a perspective view illustrating a positional relation between an attachment-preventing plate and the mother substrate.

FIG. 12 is a diagram illustrating a relation between the attachment-preventing plate and a rotation ring.

FIG. 13 is a schematic sectional view illustrating the deposition apparatus used in a deposition method according to a fourth embodiment.

FIG. 14 is a flowchart showing a process of an oblique deposition.

FIGS. 15A and 15B are diagrams illustrating a deposition for a substrate.

FIGS. 16A and 16B are diagrams illustrating different examples of slit holes.

### DESCRIPTION OF EXEMPLARY EMBODIMENTS

Hereinafter, embodiments of the invention will be described in detail with reference to the drawings.

### First Embodiment

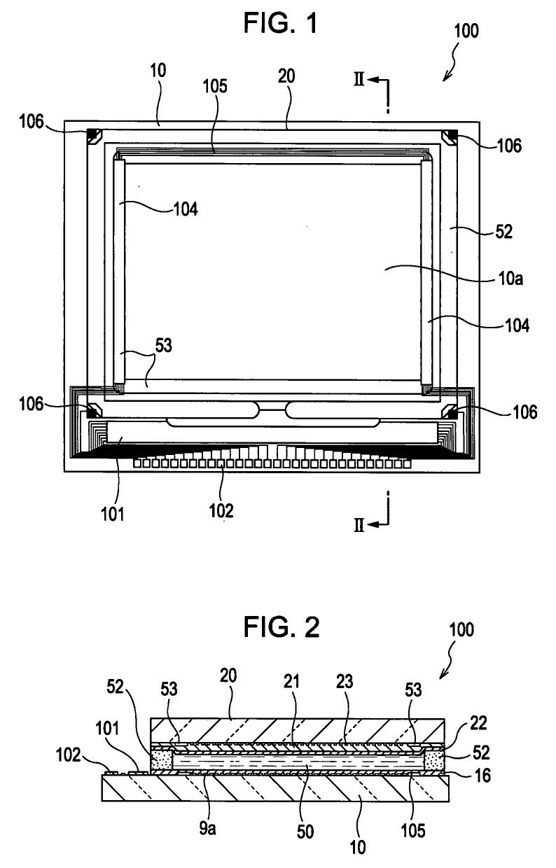

Hereinafter, a first embodiment of the invention will be described with reference to FIGS. 1 to 9. The components in the figures are not necessarily to scale, emphasis instead being placed upon illustrating each member.

First, an overall configuration of a liquid crystal device 100 manufactured on the basis of a method of manufacturing the liquid crystal device according to this embodiment will be described with reference to FIGS. 1 and 2. FIG. 1 is a top view illustrating the liquid crystal device when a TFT array substrate and elements formed thereon are viewed from a counter substrate. FIG. 2 is a sectional view illustrating the liquid crystal device taken along the line H-H′ shown in FIG. 2. As one example of the liquid crystal device, a transmissive liquid crystal device of a TFT active matrix driving type with a driving circuit is exemplified.

The liquid crystal device 100 includes a TFT array substrate 10 and a counter substrate 20 made of glass, quartz, or the like with a liquid crystal layer 50 interposed therebetween. The liquid crystal device 100 displays an image on an image display area 10a by changing alignment of the liquid crystal layer 50, changing light which is incident from the counter substrate 20, and emitting the light from the TFT array substrate 10.

As shown in FIGS. 1 and 2, the TFT array substrate 10 and the counter substrate 20 are opposed to each other in the liquid crystal device 100. The TFT array substrate 10 and the counter substrate 20 are attached to each other by a seal member 52 disposed in a seal area positioned in a periphery of the image display area 10a. The liquid crystal layer 50 is sealed to be interposed between the TFT array substrate 10 and the counter substrate 20. Moreover, in the seal member 52, gap materials such as glass fiber or glass bead scatter in order to set a gap between the TFT array substrate 10 and the counter substrate 20 to a predetermined value.

In the inside of the seal area in which the seal member 52 are disposed, a frame light-shielding film 53 for defining a frame area of the image display area 10a is disposed in the counter substrate 20. Moreover, a part or the entire of such a frame light-shielding film 53 may be disposed in the TFT array substrate 10 as a built-in light-shielding film.

In the liquid crystal device 100, there is a non-display area in the periphery of the image display area 10a. In other words, when particularly viewed from the center of the TFT array substrate 10, an area beyond the frame light-shielding film 53 is defined as the non-display area. In the non-display area, data line driving circuits 101 and mounting terminals 102 are formed along one side of the TFT array substrate 10 in an area placed in the outside of the seal area in which the seal member 52 is disposed. As not shown, the liquid crystal device 100 and an exterior device such as a control device of an electronic device are electrically connected by connecting a flexible print board or the like to the mounting terminals 102 exposed to a surface of the TFT array substrate 10.

Scanning line driving circuits 104 are formed along two sides adjacent to the one side of the TFT array substrate 10 in which the data line driving circuits 101 and the mounting terminals 102 are formed. Moreover, the scanning line driving circuits 104 are formed so as to be covered with the frame light-shielding film 53. In addition, the two scanning line driving circuits 104 are connected with each other by a plurality of wire lines 105 formed along the remaining one side of the TFT array substrate 10, that is, a side opposite the one side of the TFT array substrate 10 in which the data line driving circuits 101 and the mounting terminals 102 are formed and covered with the frame light-shielding film 53.

At least in one corner of the counter substrate 20, a vertical conductive member 106 is formed as a vertical conductive terminal electrically connecting the TFT array substrate 10 to the counter substrate 20. Meanwhile, in the TFT array substrate 10, a vertical conductive terminal is formed in an area corresponding to the vertical conductive member 106. The TFT array substrate 10 and the counter substrate 20 are electrically connected to each other through the vertical conductive member 106 and the vertical conductive terminal.

As shown in FIG. 2, on the TFT array substrate 10, an inorganic alignment film 16 such as an oblique alignment deposition film is formed on pixel electrodes 9a after pixel switching TFTs and wire lines such as scanning lines or data lines are formed. Meanwhile, counter electrodes 21 and a light-shielding film 23 with a reticular pattern or stripe pattern are formed on the counter substrate 20, and an inorganic alignment film 22 such as the oblique alignment deposition film is formed on the uppermost layer thereof. The inorganic alignment layers 16 and 22 formed on the surfaces of which the TFT array substrate 10 and the counter substrate 20 come in contact with the liquid crystal layer 50 are made of an inorganic material such as SiO₂, SiO, or MgF₂. In the first embodiment, the inorganic alignment films 16 and 22 are formed by an oblique deposition method of depositing an inorganic material such as SiO₂, SiO, or MgF₂ and formed on the surface of the TFT array substrate 10 and the counter substrate 20 so as to form a predetermined angle, respectively. In this case, the inorganic alignment film 16 on the TFT array substrate 10 is formed so as not to be attached to the mounting terminals 102. The liquid crystal layer 50 is formed of, for example, one type of liquid crystal or mixture liquid crystal in which various types of nematic liquid crystal are mixed. The liquid crystal layer 50 is in a predetermined alignment between a pair of the inorganic alignment layers 16 and 22.

A polarizing film, a phase difference film, a polarizing plate, or the like are disposed in a predetermined direction on a surface on which incident light is incident and a surface on which emitting light emits in accordance with, for example, an operating mode such as a twisted nematic (TN) mode, a super twisted nematic (STN) mode, or a vertical alignment (VA) mode or a normally-white mode/normally-black mode.

In the liquid crystal device 100 having the above-described configuration, as an alignment film for controlling alignment of liquid crystal molecules, the inorganic alignment film made of an inorganic material such as SiO₂, SiO, or MgF₂ is formed. The inorganic alignment film made of the inorganic material has a better light resistance and a better heat resistance than an alignment film made of an organic material such as polyimide. Accordingly, since there is no aging degradation, it is possible to realize an electro-optical device without deterioration of a display quality.

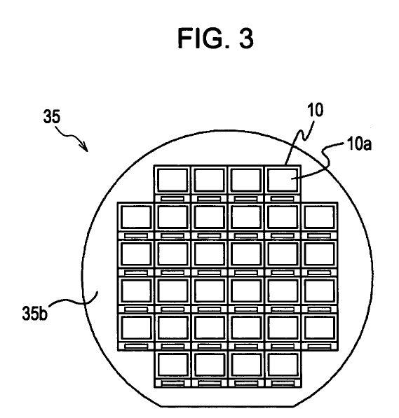

The liquid crystal device 100 manufactured by a method of manufacturing the liquid crystal device according to the first embodiment is made in a manner in which the plurality of liquid crystal devices 100 formed as an incorporated body are cut into pieces. That is, the liquid crystal device 100 is formed by a method of obtaining multiple surfaces from a mother substrate, which is a large-scale substrate. FIG. 3 is a top view illustrating a mother substrate 35 which is a substrate for an electro-optical device.

As shown in FIG. 3, the plurality of TFT array substrates 10 constituting the liquid crystal devices 100 are formed regularly in row and column directions at a predetermined interval on a substrate surface 35b of the mother substrate 35 having a circular shape.

In the first embodiment, before the plurality of TFT array substrates 10 are cut into pieces, the inorganic alignment film 16 is formed on the substrate surface 35b of the mother substrate 35. The inorganic alignment film 16 formed on the mother substrate 35 is formed by a deposition apparatus 300 described below.

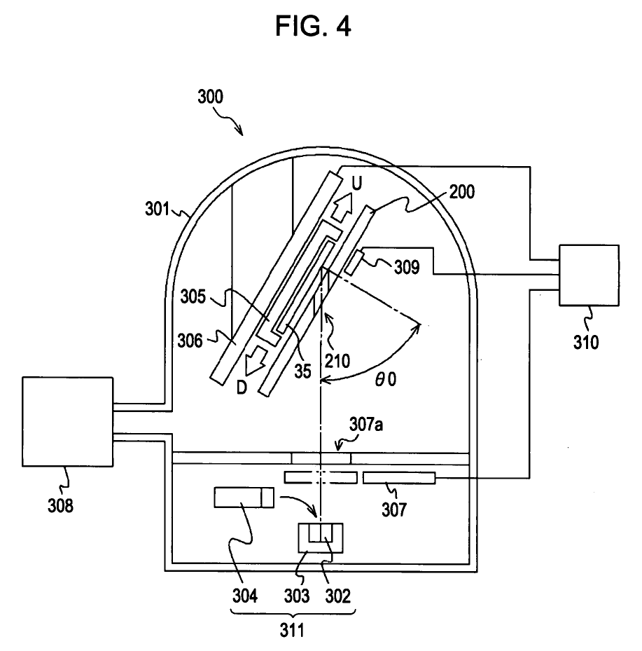

Next, a manufacture apparatus used in a method of manufacturing the liquid crystal device according to the first embodiment will be described with reference to FIG. 4. The inorganic alignment film 16 made of a deposition material such as SiO₂ is formed on the substrate 35b of the mother substrate 35 using an oblique alignment deposition method by the deposition apparatus 300 which is the manufacture apparatus used in the method of manufacturing the liquid crystal device according to the first embodiment. FIG. 4 is a schematic sectional view illustrating a configuration of the deposition apparatus 300. In addition, an upside of FIG. 4 refers to an upside of the deposition apparatus 300.

As shown in FIG. 4, the deposition apparatus 300 includes a controller 310 constituted by a calculation unit, a memory unit, and the like and a vacuum chamber 301 for keeping the inside airtight. In the vacuum chamber 301, a deposition source 311 having a deposition material 302, a substrate holder 305 and an linear movement stage 306 which are moving mechanisms, a mask 200 which is a mask member, and a shutter 307 which is a shielding mechanism are disposed.

The deposition apparatus 300 includes a vacuum pump connected to the inside of the vacuum chamber 301. The inside of the vacuum chamber 301 becomes a vacuum state (depressurization state) by discharging air of the vacuum chamber 301 using the vacuum pump 308 during a deposition process described below.

The deposition source 311 includes a crucible 303 receiving the deposition material 302 and an electron gun 304 heating the deposition material 302. The deposition source 311 generates vapors of the deposition material 302 by irradiating electron beams generated by the electron gun 304 to the deposition material 302 and heating and vaporizing the deposition material 302 in a vacuum state.

A slit hole 210 of the mask 200 is fixed in a right upward direction of the deposition material 302. The slit hole 210 is a thin long hole formed through the mask 200 and is formed so that the longitudinal direction thereof is faced to a horizontal direction.

The substrate holder 305 supporting the mother substrate 35 and the linear movement stage 306 are disposed in an upward direction of the mask 200. The substrate holder 305 supports the mother substrate 35 by facing a substrate surface 35b to be subjected to the deposition process toward the deposition material 302. The substrate holder 305 is supported so as to be movable in one direction by the linear movement stage 306 constituted by a uniaxial robot or the like which can move in a linear direction. The linear movement stage 306 is electrically connected to the controller 310. In addition, the controller 310 controls the linear movement stage 306 to move the mother substrate 35. A movement axis of the linear movement stage 306 is inclined by a predetermined angle relative to a vertical axis.

The substrate holder 305 and the linear movement stage 306 which are the moving mechanisms movably support the mother substrate 35 so that the center of the deposition material 302 and the center of the slit hole 210 forms a linear line (dotted line shown in FIG. 4), that is, an angle formed by the vertical axis and a normal line of the substrate surface 35b of the mother substrate 35 normally becomes θ0. Accordingly, The mother substrate 35 supported by the substrate holder 305 is moved in parallel in an upward direction (arrow U direction shown in FIG. 4) or a downward direction (arrow D direction shown in FIG. 4) on a plane including the substrate surface 35b. Hereinafter, the angle θ0 refers to a deposition angle.

The shutter 307 is disposed between the mask 200 and the deposition material 302. The shutter 307 which is the shielding mechanism is a device shielding or opening a vapor passage 307a facing from the deposition material 302 to the mask 200 and the mother substrate 35. A driving unit (not shown) of the shutter 307 is electrically connected to the controller 310. The passage 307a is shielded or opened in accordance with a drive of the shutter 307 by a signal of the controller 310.

A film thickness measuring sensor 309 which is a film thickness measuring mechanism is disposed on an area closed to the deposition material 302 of the mask 200. The film thickness measuring sensor 309, which is a known film thickness measuring system using a crystal oscillator, measures a thickness of a film deposited in the crystal oscillator from a variation in a unique frequency of the crystal oscillator caused by the film thickness of the deposition material deposited in the crystal oscillator. The film thickness measuring sensor 309 is disposed in the vicinity of the slit hole 210 of the mask 200 and can measure the film thickness of the deposition material deposited on the mother substrate 35 through the slit hole 210. The film thickness measuring sensor 309, which is electrically connected to the controller 210, transmits the measurement result of the deposited film thickness to the controller 310.

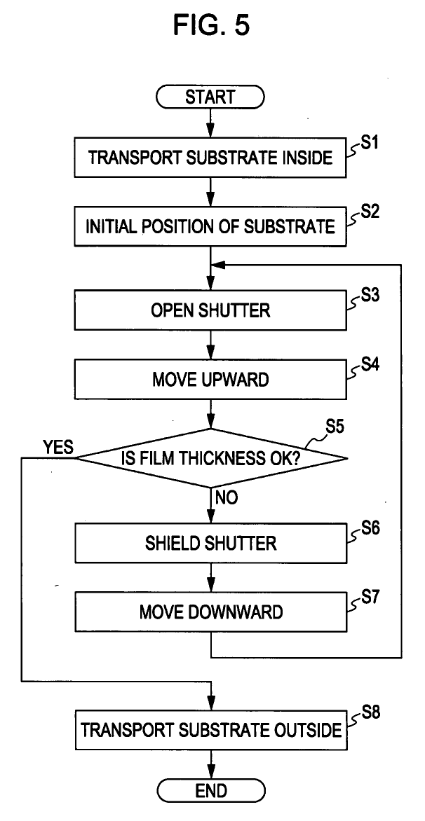

Next, a process of depositing the inorganic alignment film 16 on the surface of the mother substrate 35 using the deposition apparatus 300 will be described below. FIG. 5 is a flowchart showing the process of depositing the inorganic alignment film 16.

The process described below is performed when the inside of the vacuum chamber 301 of the deposition apparatus 300 becomes the vacuum state using the vacuum pump 308, the deposition material 302 of the deposition source 311 is heated, and vapors of the deposition material 302 is generated.

First, the mother substrate 35 is transported into the inside of the vacuum chamber 301 by the transport device (not shown), and then fixed on the substrate holder 305 (step S1).

Next, the controller 310 drives the linear movement stage 306 to move the mother substrate 35 to an initial position. In this case, the initial position according to the first embodiment is a position in which the mother substrate 35 is positioned in the lowest portion (arrow D direction) (step S2).

Next, the controller 310 moves the shutter 307 to an opening position. In this way, the vapor passage 307a facing from the deposition material 302 to the mask 200 and the mother substrate 35 is opened (step S3).

Next, the controller 310 moves the linear movement stage 306 in the upward direction (arrow U direction) at a fixed velocity V1 (step S4). The substrate surface 35b of the mother substrate 35 is exposed to the deposition material 302 through the slit hole 210. The movement of the linear movement stage 306 is performed until the entire substrate surface 35b of the mother substrate 35 is completely exposed to the deposition material 302 through the slit hole 210. Vapors of the deposition material 302 reaches the entire substrate surface 35b of the mother substrate 35 so as to form a predetermined deposition angle through the slit hole 210. In this way, the deposition material which becomes the inorganic alignment film 16 is deposited.

Next, the controller 310 controls the film thickness measuring sensor 309 to measure the film thickness deposited on the substrate surface 35b of the mother substrate 35 (step S5). When the film thickness deposited on the substrate surface 35b is sufficient to form the inorganic alignment film 16, step S8 proceeds. Subsequently, the mother substrate 35 is transported from the vacuum chamber 301 by the transport device (not shown), and then the process of forming the inorganic alignment film 16 ends.

Alternatively, when the film thickness deposited on the substrate surface 35b is not sufficient to form the inorganic alignment film 16, the next step S6 proceeds. The controller 310 moves the shutter 307 to a shielding position. In this way, the vapor passage 307a facing from the deposition material 302 to the mask 200 and the mother substrate 35 is shielded (step S6).

Next, the controller 310 moves the linear movement stage 306 in the downward direction (arrow D direction) at a fixed velocity V2 and returns the linear movement stage 306 to the initial position (step S7). In this case, since the shutter 307 is in the shielding position, the deposition material is not deposited on the substrate surface 35b of the mother substrate 35. After the movement of the linear movement stage 306 to the initial position ends, the present step returns to step S3.

In the first embodiment, the oblique deposition process of depositing the deposition material through the slit hole 210 on the substrate surface 35b of the mother substrate 35 which reciprocates in the upward and downward directions relative to the mask 200 having the slit hole 210 is performed on a side opposite the deposition material 302 only when the mother substrate 35 moves in the upward direction.

Whether the film thickness of the deposition film is sufficient or not may depend on the number of performance of the oblique deposition.

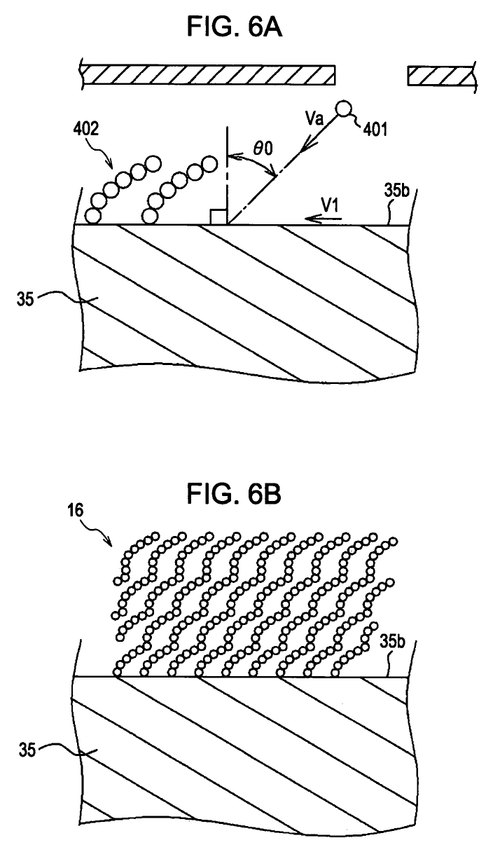

The inorganic alignment film 16 deposited on the substrate surface 35b of the mother substrate 35 by the above-described method will be described with reference to FIGS. 6A and 6B. In step S4, as shown in FIG. 6A, when the mother substrate 35 is moved in the upward direction, deposition molecules 401 travel on the substrate surface 35b through the slit hole 210. The deposition molecules 401 travel at a velocity Va so as to form the deposition angle θ0 relative to the normal line of the substrate surface 35b.

In this case, the mother substrate 35 moves at a velocity V1 in the upward direction which is the same direction as a travel direction of the deposition molecules 401 traveling at the velocity Va. Accordingly, an angle in which the deposition molecules 401 are deposited on the substrate surface 35b is determined by a synthesized velocity of the velocities of the mother substrate 35 and the deposition molecules 401 and has a tendency to be larger than the deposition angle θ0. That is, as shown in FIG. 6A, an alignment 402 of the molecules 401 deposited on the substrate surface 35b is slanted toward the substrate surface 35b.

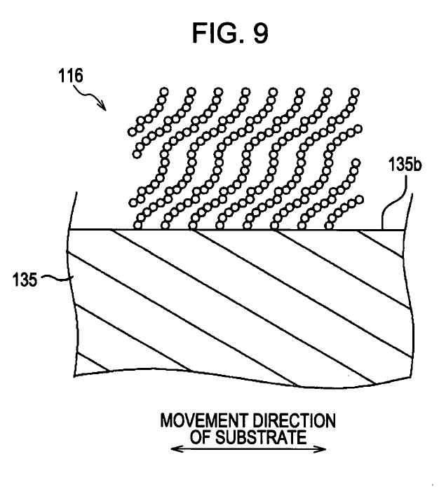

The inorganic alignment film 16 according to the first embodiment is formed in a manner in which layers having a structure in which the deposition molecules are inclined in the same direction so as to be arranged uniformly are stacked, as shown in FIG. 6B. Accordingly, compared to an alignment film 116 (see FIG. 9) formed by performing the oblique deposition on a reciprocating substrate in a known example, variation in the alignment of the molecules constituting the inorganic alignment film 16 formed according to the first embodiment becomes smaller. That is, since the oblique deposition of depositing the inorganic alignment film 16 according to the first embodiment is selectively performed only when the substrate is moved in one direction, a column structure of the inorganic alignment film 16 has directivity. Accordingly, it is possible to restrain the variation in pretilt angles in the substrate surface 35b more than that in the known example.

In this way, since the variation in the pretilt angle in the substrate surface 35b of the mother substrate 35 can be prevented, the variation in a display quality of each of the finally cut liquid crystal devices 100 becomes smaller. As a result, it is possible to improve manufacturing efficiency of the liquid crystal device 100.

### Second Embodiment

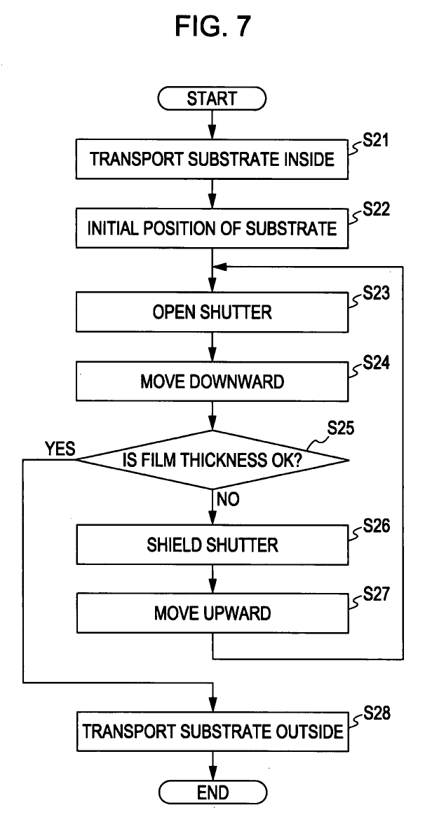

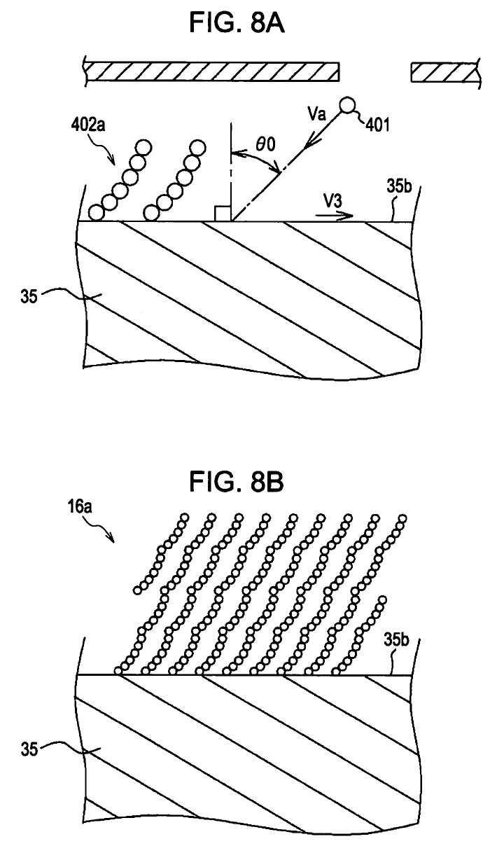

Hereinafter, a second embodiment of the invention will be described with reference to FIGS. 7, 8A, and 8B. A method of manufacturing a liquid crystal device according to a second embodiment is the same as that according to the first embodiment other than a deposition process of an inorganic alignment film 16a. Accordingly, a difference between the first and second embodiments will be described below. The same reference numerals are given to the same components according to the first embodiment and the description will be omitted. FIG. 7 is a flowchart showing a process of depositing the inorganic alignment film 16a according to the second embodiment. FIGS. 8A and 8B are schematic diagrams illustrating alignment of molecules of the inorganic alignment film 16a.

In the second embodiment, the same deposition apparatus 300 according to the first embodiment is used in the deposition process of the inorganic alignment 16a.

First, a mother substrate 35 which is transported in a vacuum chamber 301 by a transport device (not shown) is fixed on a substrate holder 305 (step S21).

Next, a controller 310 drives a linear movement stage 306 and moves the mother substrate 35 to an initial position. In the second embodiment, the initial position is a position in which the mother substrate 35 is positioned in the uppermost upward direction (arrow U direction) (step S22).

Next, the controller 310 moves a shutter 307 to an opening position. In this way, a vapor passage 307a facing from a deposition material 302 to a mask 200 and the mother substrate 35 is opened (step S23).

Next, the controller 310 moves the linear movement stage 306 in a downward direction (arrow D direction) at a fixed velocity V3 (step S24). Vapors of the deposition material 302 reaches an entire surface of a substrate surface 35b of the mother substrate 35 so as to form a predetermined deposition angle, and thus the deposition material to become the inorganic alignment film 16a is deposited.

Next, the controller 310 controls a film thickness measuring sensor 309 to measure a film thickness deposited on the substrate surface 35b of the mother substrate 35 (step S25). When the thickness of the film deposited on the substrate surface 35b is sufficient to form the inorganic alignment film 16a, step S28 proceeds. The mother substrate 35 is transported from the vacuum chamber 301 by the transport device (not shown), and then the process of forming the inorganic alignment film 16a ends.

Alternatively, the film thickness deposited on the substrate surface 35b is not sufficient to form the inorganic alignment film 16a, the next step S26 proceeds. The controller 310 moves the shutter 307 to a shielding position. Accordingly, the vapor passage 307a facing from the deposition material 302 to the mask and the mother substrate 35 is blocked (step S26).

Next, the controller 310 moves the linear movement stage 306 in the upward direction (arrow U direction) at a fixed velocity V4 and returns the linear movement stage 306 to the initial position (step S27). In this case, since the shutter 307 is in the shielding position, the deposition material is not deposited on the substrate surface 35b of the mother substrate 35. After the linear movement stage 306 moves to the initial position, the present step returns to step S23.

Unlike the first embodiment, in the second embodiment, only when the mother substrate 35 reciprocating in the upward and downward directions moves in the downward direction in a state where the mask 200 having a slit hole 210 is opposed to the deposition material 302, an oblique deposition is performed on the substrate surface 35b through the slit hole 210. The oblique deposition reiterates until the sufficient film thickness is deposited to form the inorganic alignment film 16a.

The inorganic alignment film 16a deposited on the substrate surface 35b of the mother substrate 35 by the method according to the above-described embodiment will be described with reference to FIGS. 8A and 8B. In step S24, when the mother substrate 35 moves in the downward direction, as shown in FIG. 8A, the deposition molecules 401 travel on the substrate surface 35b through the slit hole 210. The deposition molecules 401 travel so as to form a deposition angle θ0 relative to a normal line of the substrate surface 35b at a velocity Va.

The mother substrate 35 moves at the velocity V3 in the downward direction which is the direction opposite to a travel direction of the deposition molecules 401 traveling at the velocity Va. Accordingly, an angle in which the deposition molecules 401 are deposited on the substrate surface 35b is determined by a synthesized velocity of the velocities of the mother substrate 35 and the deposition molecules 401 and has a tendency to be smaller than the deposition angle θ0. That is, as shown in FIG. 8A, an alignment 402a of the deposition molecules 401 is formed so as to be erect from the substrate surface 35b.

The inorganic alignment film 16a according to the second embodiment is formed in a manner in which layers having a structure in which the deposition molecules are erect in the same direction so as to be arranged uniformly are stacked, as shown in FIG. 8B. Accordingly, compared to an alignment film 116 (see FIG. 9) formed by performing the oblique deposition on a reciprocating substrate in a known example, variation in the alignment of the molecules constituting the inorganic alignment film 16a formed according to the second embodiment becomes smaller. That is, like the first embodiment, since the oblique deposition of depositing the inorganic alignment film 16a according to the second embodiment is selectively performed only when the substrate is moved in one direction, a column structure of the inorganic alignment film 16a has directivity. Accordingly, it is possible to restrain the variation in pretilt angles in the substrate surface 35b more than that in the known example.

### Third Embodiment

In a third embodiment, an inorganic alignment film 16 is formed on a substrate surface 35b of a mother substrate 35 before a plurality of TFT array substrates 10 are cut into pieces. The inorganic alignment film 16 on the mother substrate 35 is formed by a deposition apparatus 500 described below.

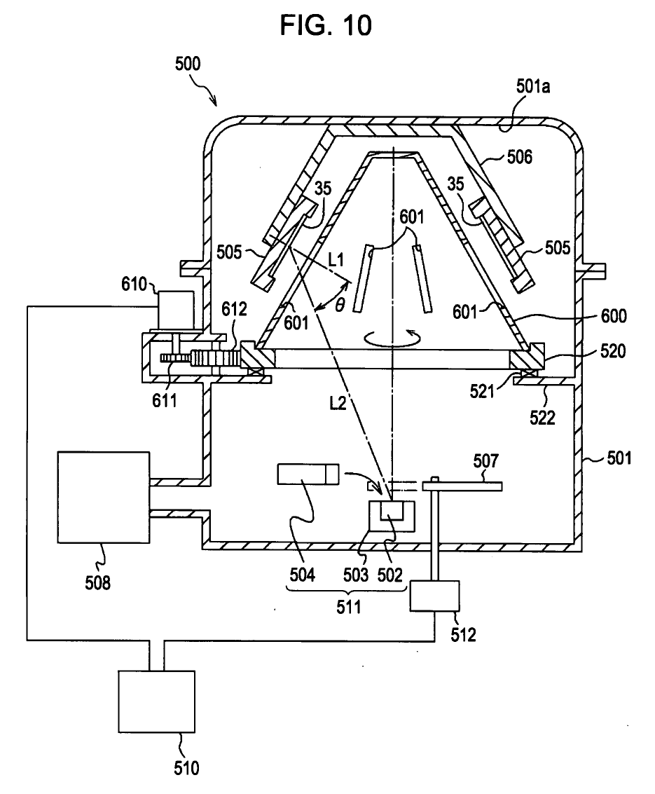

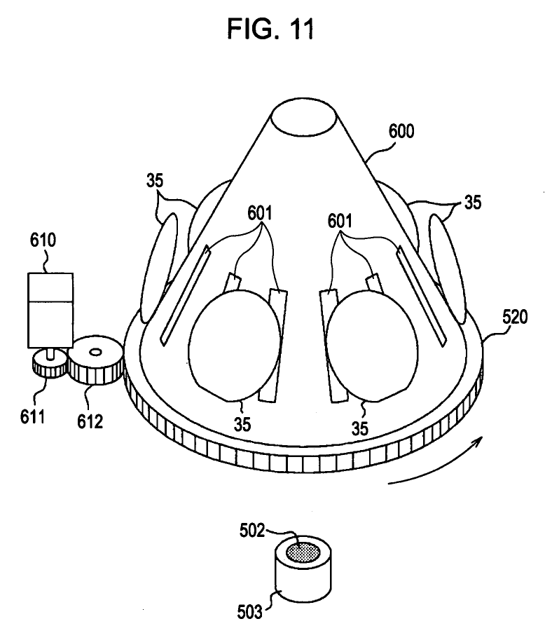

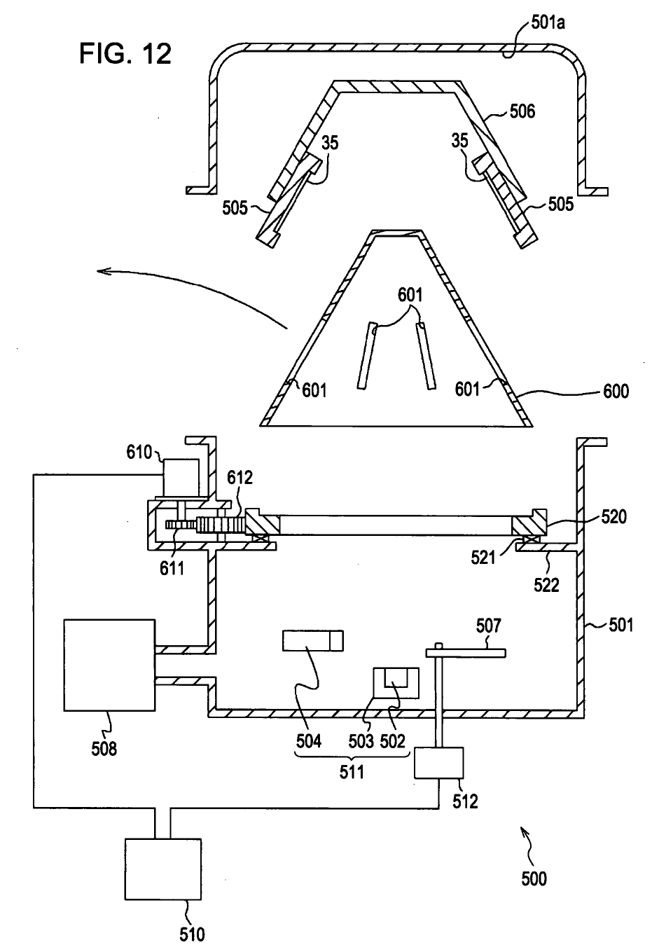

Next, the deposition apparatus 500 according to the third embodiment will be described with reference to FIGS. 10 to FIG. 12. The deposition apparatus 500, which is a manufacturing apparatus of a liquid crystal device 100, form the inorganic alignment film 16 made of a deposition material such as SiO₂ on the substrate surface 35b of the mother substrate 35 using an oblique deposition method. FIG. 10 is a schematic sectional view illustrating a configuration of the deposition apparatus 500. FIG. 11 is a perspective view illustrating a positional relation between an attachment-preventing plate and the mother substrate. FIG. 12 is a diagram illustrating a relation between the attachment-preventing plate and a rotation ring. In the following description, an upward direction of FIG. 10 is the upward direction of the deposition apparatus 500.

As shown in FIG. 10, the deposition apparatus 500 includes a controller 510 constituted by a calculation unit, a memory unit, and the like and a vacuum chamber 501 for keeping the inside airtight. In the vacuum chamber 501, a deposition source 511 having a deposition material 502, a substrate holder 505 and a bracket 506 which are substrate support mechanisms, an attachment-preventing plate 600, a shutter 507 which is a shielding mechanism, and a rotation ring 520 which is a rotating mechanism are disposed.

The deposition apparatus 500 includes a vacuum pump 508 connected to the inside of the vacuum chamber 501. The inside of the vacuum chamber 501 becomes a vacuum state (depressurization state) by discharging air of the vacuum chamber 501 using the vacuum pump 508 during a deposition process described below.

The deposition source 511 includes a crucible 503 receiving the deposition material 502 and an electron gun 504 heating the deposition material 502. The deposition source 511 generates vapors of the deposition material 502 by irradiating electron beams generated by the electron gun 504 to the deposition material 502 and heating and vaporizing the deposition material 502 in a vacuum state. Moreover, as not shown, a device supplying the deposition material 502 to the crucible 503 is arranged in the vacuum chamber 501.

The attachment-preventing plate 600 is arranged in a right upward direction of the deposition material 502. As shown in FIGS. 10 and 11, the attachment-preventing plate 600 is a member having a substantially conical opening formed downward, that is, in a direction of the deposition material 502 and being enlarged in an opening direction. The attachment-preventing plate 600 has the conical shape molded in a conical shape made of a stainless steel sheet with a predetermined thickness. The opening having the conical shape is formed downward and a central axis is identical with a vertical line passing through a center of the deposition material 502.

On a side surface of the attachment-preventing plate 600, a plurality of slit holes 601 which are through-holes with a narrow long rectangular shape extending toward the opening having the conical shape are formed in a peripheral direction at an identical interval. The plurality of slit holes 601 have a substantially identical shape. Longer sides of the slit holes 601 are formed in a radial shape at an identical distance in a diameter direction from the attachment-preventing plate 600 along the diameter direction right below the attachment-preventing plate 600, that is, when viewed from the deposition material 502. That is, when the attachment-preventing plate 600 is disposed in the vacuum chamber 501, the plurality of slit holes 601 are formed at the substantially identical distance from the deposition material 502.

The attachment-preventing plate 600 according to the third embodiment is made of the stainless steel sheet. An alumina sprayed coating is formed on a surface of the attachment-preventing plate 600. A material of the attachment-preventing plate 600 is not limited to the stainless, but may be steel, aluminum, a resin, or the like. A surface treatment may not be performed by the sprayed coating. As described in detail below, it is desirable that the material of the attachment-preventing plate 600 and the surface treatment have high adhesion to an undesirable deposition material so as not to peel off and have endurance when the attached deposition is removed.

The attachment-preventing plate 600 with the above-described shape is placed on a substantial circular rotating ring 520 which is disposed so as to rotate on a substantial horizontal plane in the vacuum chamber 501. The rotating ring 520 is rotatably supported on a flange 522 protruding in an inner direction from a sidewall of the vacuum chamber 501 with a bearing 521 interposed therebetween. The rotating ring 520 is disposed in the vacuum chamber 501 so that a rotational axis is identical with the vertical line passing through the center of the deposition material 502. In other words, the rotating ring 520 rotates on the vertical line on the horizontal plane perpendicular to the vertical line passing through the center of the deposition material 502.

The rotating ring 520 has a concave portion on which a bottom surface of the attachment-preventing plate 600 is fixed so that the attachment-preventing plate 600 is placed on a top surface of the rotating ring 520. When the attachment-preventing plate 600 is placed on the rotating ring 520, a central axis of the rotating ring 520 is substantially identical with that of the attachment-preventing plate 600. That is, the attachment-preventing plate 600 is rotatably supported on the vertical line passing through the center of the deposition material 502 by the rotating ring 520.

A gear is disposed in a sidewall of the rotating ring 520. A rotational drive force of an electric motor 610 disposed on the sidewall of the vacuum chamber 501 rotates the rotating ring 520 through a drive gear 611 and an idle gear 612. The electric motor 520 is electrically connected to a controller 510 and the controller 510 controls the rotating ring 520 to rotate, that is, the attachment-preventing plate 600 to rotate.

A plurality of substrate holders 505 supporting the mother substrate 35 are disposed above the above-described attachment-preventing plate 600. The substrate holders 505 are fixed on a ceiling portion 501 of the vacuum chamber 501 through the bracket 506. The substrate holders 505 support the mother substrates 35 so that the substrates 35b are opposed to the deposition material 502.

Each of the substrate holders 505 supports the mother substrate 35 so that a line L2 between the center of the substrate surface 35b and the center of the deposition material 502 and a normal line L1 of the substrate surface 35b form a predetermined angle θ. Moreover, each of the substrate holders 505 supports the mother substrate 35 so that an depositing area, which is a predetermined area of the substrate surface 35b of the supported the mother substrate 35, is exposed to the deposition material 502 through the slit hole 601 of the rotating attachment-preventing plate 600.

In other words, the deposition apparatus according to the third embodiment is configured so that vapors generated from the deposition material 502 reaches the entire depositing area of the substrate surface 35b of the mother substrate 35 supported by the each of the substrate holder 505 through the slit hole 601 of the rotating attachment-preventing plate 600.

The plurality of substrate holders 505 are disposed at the same interval in a peripheral direction in a periphery of the vertical line passing through the center of the deposition material 502. The plurality of substrate holders 505 are all fixed on the ceiling portion 501a of the vacuum chamber 501 by one bracket 506.

That is, the plurality of mother substrates 35 supported by the plurality of the substrate holders 505 are all disposed at the same distance from the deposition material 502. At this time, the plurality of mother substrates 35 are all supported so that the line L2 between the center of the substrate surface 35b and the center of the deposition material 502 and the normal line L1 of the substrate surface 35b form the predetermined angle θ. As shown in FIG. 11, the plurality of mother substrates 35 supported by the plurality of substrate holders 505 are disposed so that the substrate surfaces 35b are on the outer surface of the attachment-preventing plate 600.

As shown in FIG. 12, the vacuum chamber 501 of the deposition apparatus 500 according to the third embodiment can be opened by upward detaching the ceiling portion 501a. When the ceiling portion 501a is detached, the attachment-preventing plate 600 can be transported from or to the vacuum chamber 501. The bracket 506 supporting the plurality of substrate holders 505 is fixed so as to be attached to or detached from the ceiling portion 501a. The plurality of mother substrates 35 can be transported from the vacuum chamber 501 to the vacuum chamber 501 by setting the mother substrates 35 on the plurality of substrate holders 505 fixed on the bracket 506, fixing the bracket 506 on the ceiling portion 501a, and by covering the vacuum chamber 501.

The shutter 507 is disposed between the attachment-preventing plate 600 and the deposition material 502. The shutter 507, which is a shielding mechanism, shields or opens a vapor passage from the deposition material 502 to the attachment-preventing plate 600 and the mother substrates 35. A driving unit 512 of the shutter 507 is electrically connected to the controller 510. A signal from the controller 510 induces the shutter 507 to be driven. At this time, the shutter 507 opens or shields the passage.

A film thickness measuring sensor (not shown) which is a film thickness measuring unit is disposed in an area close to the deposition material 502 of the attachment-preventing plate 600. The film thickness measuring sensor, which is a known film thickness measuring system using a crystal oscillator, measures a film thickness deposited in the crystal oscillator from a variation in a unique frequency of the crystal oscillator caused by the film thickness of the deposition material deposited in the crystal oscillator. The film thickness measuring sensor, which is electrically connected to the controller 510, transmits the measurement result of the deposited film thickness to the controller 510.

A process of depositing the inorganic alignment film 16 on the substrate surface 35b of the mother substrate 35 using the deposition apparatus 500 with the above-described configuration will be described below.

First, the mother substrates 35 are put on the plurality of substrate holders 505 from the outside of the vacuum chamber 501. Next, the bracket 506 supporting the plurality of substrate holders 505 is fixed on the ceiling portion 501a to shield the vacuum chamber 501. In this way, the mother substrates 35 are transported into the vacuum chamber 501. Before the mother substrates 35 are transported, the attachment-preventing plate 600 is fixed on the rotating ring 520.

Next, by operating a vacuum pump 508, air in the vacuum chamber 501 is discharged to make the inside of the vacuum chamber 501a vacuum state (depressurization state). When a pressure of the vacuum chamber 501 becomes a predetermined state, an electronic gun 504 emits electronic beams to heat the deposition material 502 and generate vapors of the deposition material 502.

The electric motor 610 is driven to rotate the rotating ring 520 at a predetermined rotation speed. That is, the attachment-preventing plate 600 starts to rotate around the periphery of the central axis. Subsequently, the shutter 507 is moved to an opening position to open the vapor passage facing from the deposition material 502 to the attachment-preventing plate 600 and the mother substrate 35.

In this way, the vapors of the deposition material 502 reaches the depositing area of the substrate surface 35b of each of the mother substrates 35 so as to form a predetermined deposition angle θ through the slit hole 601 of the rotating attachment-preventing plate 600, and then the deposition material 502 which becomes the inorganic alignment film 16 is deposited on the depositing area.

The film thickness measuring sensor measures the film thickness deposited on the substrate surface 35b of each of the mother substrate 35, and then outputs the measurement result. When the film thickness is thick enough to become the inorganic alignment film 16, the shutter 507 moves to the shielding position to shield the vapor passage facing from the deposition material 502 to the attachment-preventing plate 600 and the mother substrate 35. The film thickness of the deposited film may be measured on the basis of the time of performing the deposition, that is, a period of time while the shutter 507 moves to the opening position and moves to the shielding position again.

Subsequently, the mother substrates 35 are transported to the outside of the vacuum chamber 501. At this time, the process of forming the inorganic alignment film 16 by the deposition apparatus 500 ends.

The deposition apparatus 500 according to the third embodiment can form the inorganic alignment films 16 on the substrate surfaces 35b of the plurality of mother substrate 35 so as to form the deposition angle θ. In this case, since the vapors of the deposition material 502 can reach the substrate surfaces 35 only through the slit holes 601 of the attachment-preventing plate 600, it is possible to uniformly form the inorganic alignment films 16.

Hereinafter, advantages of the deposition apparatus 500 with the above-described configuration will be described.

The deposition apparatus 500 according to the third embodiment includes the attachment-preventing plate 600 and the substrate holders 505. The attachment-preventing plate 600 with a conical shape opens toward the deposition material 502 and is enlarged in an opening direction. In addition the attachment-preventing plate 600 has the slit holes extending in the opening direction on a side surface. The substrate holders 505 support the mother substrates 35 so that the substrate surfaces 35b are opposed to the outside surface of the attachment-preventing plate are opposed to the deposition material 502 so as to form the predetermined angle θ. The inorganic alignment films 16 are formed by rotating the attachment-preventing plate on the central axis passing through the center of the deposition material 502 and by allowing the substrate surfaces 35b to be exposed to the deposition material 502 through the slit holes 601.

According to the deposition apparatus 500 with the above-described configuration, the uniform inorganic alignment films 16 can be obtained by performing the deposition through the slit holes 601. At this time, the undesirable deposition material traveling in the upward direction from the attachment-preventing plate 600 normally passes through the slit holes 601. Accordingly, since the undesirable deposition material can be prevented from depositing on the ceiling portion 501a of the vacuum chamber 501, it is possible to prevent the undesirable deposition material from affecting the working of the deposition apparatus 500.

Since the attachment-preventing plate 600 on which the undesirable deposition material is deposited has a substantially conical shape, the attachment-preventing plate 600 can collect a large amount of the undesirable deposition material more than the known attachment-preventing plate with a flat shape.

That is, the attachment-preventing plate 600 can function for a longer time and a removing working of the undesirable deposition material deposited on the attachment-preventing plate 600 is not required to be performed for a long time. Accordingly, since the removing working in the deposition apparatus 500 can be shortened more than the known deposition apparatus, it is possible to improve efficiency of the apparatus. Moreover, the substantially conical attachment-preventing plate 600 can be made by a bending working of a steel sheet.

The deposition apparatus 500 according to the third embodiment includes the rotating ring 520 rotating the attachment-preventing plate 600, which is configured to be placed on the rotating ring 520.

With such a configuration, it is possible to simply and easily perform a working of taking the attachment-preventing plate 600 from the vacuum chamber 501 or installing it in the vacuum chamber 501 for a short time. Accordingly, when the undesirable deposition material deposited on the attachment-preventing plate 600 is removed, the attachment-preventing plate 600 with the substantially identical shape on which the undesirable deposition material is deposited can be prepared. Then, the attachment-preventing plate 600 can be exchanged. In this way, it is possible to resume the deposition apparatus 500.

In this case, the undesirable deposition material deposited on the attachment-preventing plate 600 which is taken out from the vacuum chamber 501 in turn can be removed independent of the operation of the deposition apparatus 500. That is, according to the third embodiment, it is possible to remove the undesirable deposition material deposited on the attachment-preventing plate 600 in the outside of the apparatus and to substitute the attachment-preventing plate 600 for a short time. As a result, it is possible to further improve the operation of the deposition apparatus 500.

The rotating ring 520 is a rotating mechanism with only one axis like that in the known example. Accordingly, the reliability of the deposition apparatus 500 with such a mechanism is not reduced. Moreover, the simple mechanism facilitates a maintenance operation and a non-operation time of the deposition apparatus can be miniaturized if a problem arises.

In the deposition apparatus 500 according to the third embodiment, the plurality of slit holes 601 are formed in the attachment-preventing plate 600. In addition, it is possible to perform the oblique deposition on the plurality of mother substrates 35.

With such a configuration, it is possible to improve throughput of the deposition apparatus 500 per a unit time.

In the above-described third embodiment, the attachment-preventing plate has the substantially conical shape. However, the invention is not limited thereto, but the attachment-preventing plate may have a substantial pyramidal shape.

### Fourth Embodiment

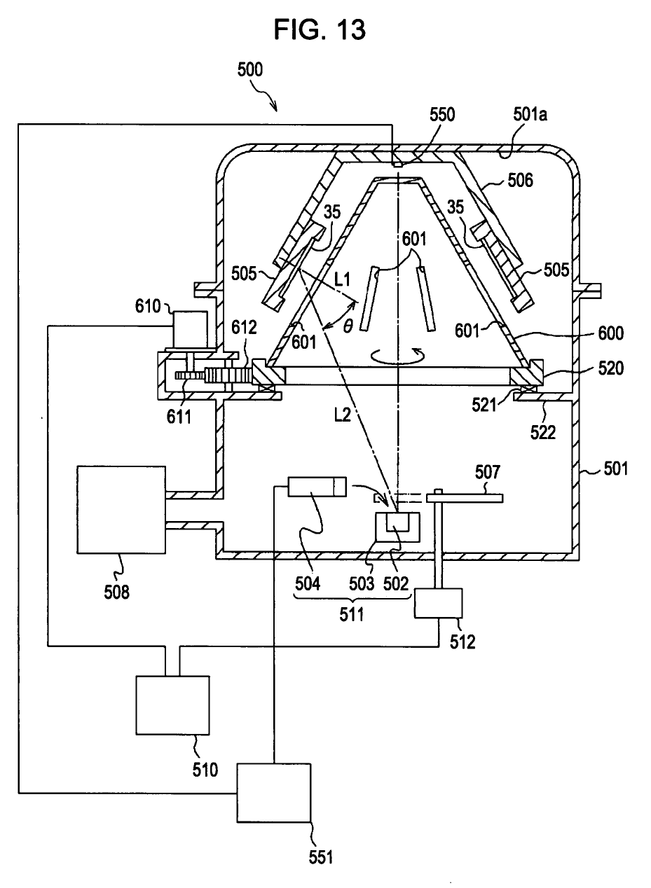

FIG. 13 is a schematic sectional view illustrating the deposition apparatus used in a deposition method according to a fourth embodiment. In FIG. 13, the same reference numerals are given to the same components shown in FIG. 10 and the description will be omitted.

In a deposition method according to the fourth embodiment, the method of manufacturing the liquid crystal device according to the first embodiment is embodied using the deposition apparatus according to the third embodiment. That is, in the deposition method according to the fourth embodiment, the deposition apparatus according to the third embodiment is driven on the basis of specific conditions.

The deposition method according to the fourth embodiment is designed to improve deposition characteristics by performing an oblique deposition while an attachment-preventing plate 600 is rotated in one direction. In the first embodiment, the uniform inorganic alignment film can be obtained by selectively performing the deposition only when the substrate moves in one direction. However, while the substrate moves in the other direction, the deposition is not performed. Accordingly, productivity may be reduced.

Accordingly, the oblique deposition according to the third embodiment is performed using the deposition apparatus according to the third embodiment while the substrate is rotated in one direction. In this way, the deposition characteristics and the productivity can be improved.

As shown in FIG. 13, a liquid crystal monitor 550 is disposed in a bracket 506. In the liquid crystal monitor 550, a deposition film is configured so that vapors of a deposition material 502 reaches through an upper end opening of the attachment-preventing plate 600 and a deposition film is deposited. The liquid crystal monitor 550 vibrates at frequencies in accordance with mass of the deposition film and outputs signals in accordance with the frequencies to an electron gun output controller 551.

On the basis of the output signals of the liquid crystal monitor 550, the electron gun output controller 551 acquires a rate (deposition rate) at which the deposition film is deposited and controls the outputs of the electron gun 504 in order to make the deposition rate uniform. In this way, it is possible to control the deposition rate so as to be uniform.

However, every substrate has its own optimum deposition angle of an inorganic alignment film. Accordingly, each substrate holder 505 is disposed so that an elevation angle formed by the vertical direction of each substrate 35 and a substrate surface is an optimum deposition angle. In addition, according to the fourth embodiment, an angle formed by the surface of a conical side of the attachment-preventing plate 600 and the vertical direction is configured to accord with the elevation angle of the substrate 35. In the fourth embodiment, since the slit holes 601 and the substrates 35 are parallel to each other, it is possible to make the deposition rate uniform.

The deposition rate in addition to the output of the electron gun 504 varies in accordance with a width and number of the slit holes 601 and a rotation speed of the attachment-preventing plate 600.

The larger the width of each of the slit holes 601 becomes, the more the deposition rate increases. However, the larger the width of each of the slit holes 601 becomes, the larger a difference in a reach angle from a center of the slit hole 601 and an end portion in a width direction to the substrate surface of the deposition material 502 becomes. Accordingly, a quality in the film may be impaired. In order to solve the above-described problem, the width the range of, for example, 10 to 25 μm is used as the width of each of the slit holes 601. Moreover, the length of each of the slit holes 601 is in the range of, for example, about 8 to 12 inches in accordance with the size of the substrate 35.

Additionally, the more the number of the slit holes 601 increases, the larger the deposition rate becomes. However, the number of the slit holes 601 is limited in accordance with a size of the substrates 35 and the slit width.

The more the rotation speed of the attachment-preventing plate 600 increases, the more the deposition rate increases. However, there is a limit to the rotation speed due to a mechanical limit. For example, in the fourth embodiment, the rotation speed in the range of 2 to 2.5 rates per minute is used as the rotation speed of the attachment-preventing plate 600.

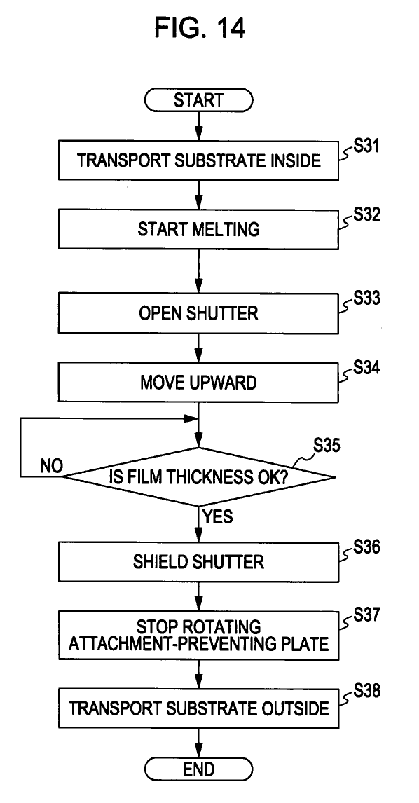

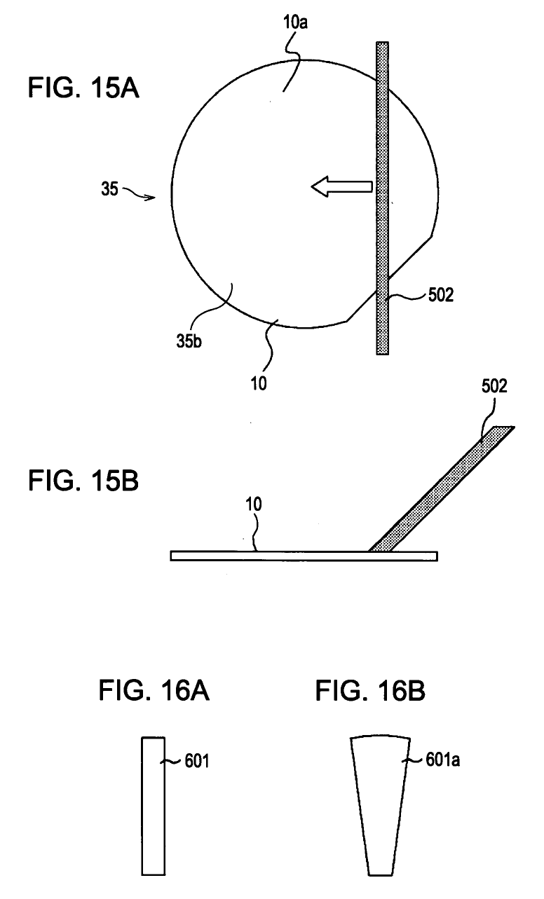

Next, an operation of the deposition apparatus with the above-described configuration will be described with reference to FIGS. 14 and 15. FIG. 14 is a flowchart showing a process of the oblique deposition. FIGS. 15A and 15B are diagrams illustrating how the deposition for each of substrates 35 is performed. FIG. 15A shows how a deposition material 502 travels when viewed from an upper surface of each of the substrates 35. FIG. 15B shows how the deposition material 502 travels when viewed from a side surface of each of the substrates 35.

In the fourth embodiment, the oblique deposition for the substrates 35 is performed while rotating the attachment-preventing plate 600 in one direction. First, the mother substrates 35 are transported into a vacuum chamber 501 by a transport device, and then fixed on substrate holders 505 (step S31).

Next, the deposition material 502 starts to be melted by heating a crucible 503 (step S32). Subsequently, a controller 510 controls an electric motor 610 to be driven to rotate a rotating ring 520 at a predetermined rotation speed in one direction (step S33). In this way, the attachment-preventing plate 600 starts to rotate in one direction along a periphery of a vertical axis.

Next, after the deposition material 502 is melted, the shutter 507 is moved to an opening position (step S34) to open a vapor passage facing from the deposition material 502 to the attachment-preventing plate 600 and the mother substrate 35. Subsequently, the vapor of the deposition material 502 reaches entire substrate surfaces 35b of the mother substrates 35 through the slit holes 601 of the attachment-preventing plate 600 so as to form a predetermined deposition angle. In this way, the deposition material which becomes an inorganic alignment film 16 is deposited.

As shown in FIGS. 15A and 15B, the deposition material 502 obliquely traveling in one direction is deposited on the mother substrates 35. Like the first embodiment, in the fourth embodiment, it is possible to stack layers having a structure in which the deposition molecules are slanted in the same direction so as to be arranged uniformly.

Since the deposition is performed during rotation of the attachment-preventing plate 600 in one direction, it is possible to perform successive deposition. Accordingly, productivity is excellent. Moreover, the electron gun output controller 551 controls the deposition rate so as to be uniform on the basis of the signal from the liquid crystal monitor 550.

When the film thickness deposited on each of the substrate surfaces 35b is not sufficient to become the inorganic alignment film 16, the controller 510 continues to rotate the attachment-preventing plate 600 in one direction and continuously allows the deposition material 502 to be deposited the substrate surface 35b of each of the mother substrates 35. Afterward, the deposition continues until a predetermined film thickness is formed.

When the inorganic alignment film 16 with the predetermined film thickness is formed, the controller 510 controls the shutter 507 to shield the vapor passage (step S36) and stop rotation of the attachment-preventing plate 600 (step S37). Subsequently, the controller 510 controls a transport device (not shown) to transport each of the mother substrate 35 outside from the vacuum chamber 501 (step S38), and then the process of forming the inorganic alignment film 16 ends.

In the above-described configuration, like the first embodiment, it is possible to form the uniform deposition film and to obtain the deposition method realizing the excellent productivity.

However, in an upper end and lower end of each of the mother substrate 35, since a distance and the deposition angle between the mother substrate 35 and the crucible 503 configuring a deposition source 511 are different, the film thickness may be nonuniform.

Accordingly, a slit hole with a shape shown in FIGS. 16A and 16B can be used. A slit hole 601a shown in FIG. 16B is different from the slit hole 601 (see FIG. 16A) shown in FIGS. 10 to 12 in that an upper end of the slit hole 601 is wider and a lower end thereof is narrower. If the slit hole 601a is used instead of the slit hole 601, a time required for the deposition material 502 to pass through each slit hole 601a is longer in the upper end than in the lower end. That is, it is possible to obtain the uniform film thickness is the upper end and the lower end of the mother substrate 35 by passing the deposition material 502 through the upper end of the mother substrate 35 for a longer time than the lower end.

The invention is not limited to the above-described embodiments, but may be modified in various forms without departing from the scope or spirit of the invention understood from the appended Claims and the foregoing description, and the method of manufacturing the liquid crystal device accompanied with the modification is considered to be included in the technical scope of the invention.

What is claimed is:

1. A method of manufacturing a liquid crystal device, in which an inorganic alignment film is deposited on the surface of a substrate by allowing a vapor, which is generated by heating a deposition material, to reach the surface of the substrate through a slit hole so as to form a predetermined angle, the substrate being opposed to the deposition material with a mask having the slit hole interposed therebetween and moving in two opposite directions,
wherein the inorganic alignment film is selectively deposited only when the substrate moves in one direction of the two opposite directions.

2. The method according to claim 1,
wherein the two opposite directions in which the substrate moves are parallel to a line obtained by projecting a segment connecting the center of the deposition material to the center of the slit hole onto the substrate surface in the normal line direction of the substrate surface, and
wherein the inorganic alignment film is deposited when the substrate moves in the same direction as a flow direction of the vapor of the deposition material.

3. The method according to claim 1,
wherein the two opposite directions in which the substrate moves are parallel to a line obtained by projecting a segment connecting the center of the deposition material to the center of the slit hole onto the substrate surface in the normal line direction of the substrate surface, and
wherein the inorganic alignment film is deposited when the substrate moves in the direction opposite to a flow direction of the vapor of the deposition material.

4. A deposition apparatus for forming a thin film on a surface of a substrate by allowing vapor generated by heating a deposition material in a vacuum chamber to reach the surface of the substrate, the deposition apparatus comprising:
an attachment-preventing plate having a conical or pyramidal opening formed toward the deposition material, being enlarged in an opening direction, and having a slit hole extending toward the opening in a side surface thereof; and
a substrate support portion supporting the substrate so that the substrate is opposed to an outer surface of the attachment-preventing plate and the substrate is opposed to the deposition material at a predetermined angle,
wherein the thin film is formed on the substrate by relatively rotating the attachment-preventing plate relative to the substrate support portion about a straight line passing through the center of the deposition material, and allowing the substrate supported by the substrate support portion to be exposed to the deposition material through the slit hole.

5. The deposition apparatus according to claim 4, further comprising a rotating unit rotating the attachment-preventing plate,
wherein the attachment-preventing plate is configured to be easily attached and detached to and from the rotating unit.

6. The deposition apparatus according to claim 4, wherein a plurality of the slit holes are formed radially when the attachment-preventing plate is viewed from the opening side.

7. The deposition apparatus according to claim 4, wherein the substrate support portion supports the substrate at a plurality of positions in a circumferential direction about the central axis of the attachment-preventing plate and opposite the outer surface of the attachment-preventing plate.

8. The deposition apparatus according to claim 4, wherein the substrate is a substrate for a liquid crystal device and the thin film is an inorganic alignment film controlling the alignment of liquid crystal molecules.

9. A deposition apparatus for forming a thin film on a surface of a substrate by allowing vapor generated by heating a deposition material in a vacuum chamber to reach the surface of the substrate, the deposition apparatus comprising:
an attachment-preventing plate having a conical or pyramidal opening formed toward the deposition material, being enlarged in an opening direction, and having a slit hole extending toward the opening in a side surface thereof; and
a substrate support portion supporting the substrate so that the substrate is opposed to an outer surface of the attachment-preventing plate and the substrate is opposed to the deposition material at a predetermined angle,
wherein the thin film is formed on the substrate by relatively rotating the attachment-preventing plate relative to the substrate support portion in one direction about a straight line passing through the center of the deposition material, and allowing the substrate supported by the substrate support portion to be exposed to the deposition material through the slit hole.

10. The deposition apparatus according to claim 9, wherein the substrate support portion supports the substrate so that the surface of the substrate and a side surface of the attachment-preventing plate are parallel to each other.

11. The deposition apparatus according to claim 9, wherein a width of a top end of the slit hole is different from that of a bottom end thereof.

12. A deposition method of forming a thin film on a surface of a substrate using the deposition apparatus according to claim 9, the deposition method comprising:
rotating an attachment-preventing plate in one direction about a central axis, which is a straight line passing through the center of a deposition material, relative to a substrate support portion; and
depositing the thin film on the surface of the substrate supported by the substrate support portion through a slit hole using the deposition material.
